(19) United States
(12) Patent Application Publication
(10) Pub. No.: US 2007/0153864 A1
(43) Pub. Date: Jul. 5, 2007

(54) Lasers and methods associated with the same

(75) Inventors: Elefterios Lidorikis, Ioannina (GR); Alexander L. Pokrovskiy, Burlington, MA (US); Alexei A. Erchak, Cambridge, MA (US)

Correspondence Address: WOLF GREENFIELD & SACKS, P.C., 600 ATLANTIC AVENUE, BOSTON, MA, 02210-2206, US

(73) Assignee: Luminus Devices, Inc., Woburn, MA (US)

(21) Appl. No.: 11/592,029

(22) Filed: Nov. 2, 2006

Related U.S. Application Data
(60) Provisional application No. 60/732,491, filed on Nov. 2, 2005.

(51) Int. Cl. H01S 5/00; H01S 3/08

(52) U.S. Cl. 372/50.124; 372/108

(57) ABSTRACT

Laser structures and related methods are provided. The lasers may be formed of semiconductor materials with most (or all) of the components being formed on a unitary structure. The lasers may include a resonator separated from a light extraction region.

### RELATED APPLICATIONS

This application claims priority to U.S. Provisional Patent Application Ser. No. 60/732,491, filed on Nov. 2, 2005, which is incorporated herein by reference.

### FIELD OF INVENTION

The invention relates generally to lasers and, more particularly, to semiconductor lasers that include a resonator separated from a light extraction region.

### BACKGROUND OF INVENTION

A laser is an optical device that emits a coherent beam of light. The light emission is stimulated by introducing energy (i.e., pumping) into a gain material. The energy is absorbed by atoms of the gain material placing the atoms in a high energy (i.e., excited) state. When the number of atoms is an excited state is greater than the number of atoms in a lower energy state, then an incident light wave produces more stimulated emission than stimulated absorption and, thus, there is a net amplification of the incident light wave.

A laser typically includes a gain material within an optical resonator (e.g., a waveguide). The resonator may be defined between two reflective surfaces (e.g., mirrors) with one of the surfaces being less reflective than the other. In general, light may bounce between the reflective surfaces passing through the gain medium a sufficient number of times to increase the power of the light. The light may be eventually be emitted through the less reflective mirror in the form of a coherent beam.

A laser may be made from semiconductor materials and manufactured using conventional semiconductor processes. For example, a plurality of laser die may be formed on a wafer. It is advantageous for the performance of such die to be evaluated when on the wafer. Also, it is advantageous for lasers to have a simple structure which can be processed relatively easily.

### SUMMARY OF INVENTION

Lasers that include a resonator separated from a light extraction region are provided.

In one aspect of the invention, the laser comprises a resonator designed to confine, at least in part, light propagating within the resonator and an extraction region separated from the resonator. The extraction region is configured to receive the light from the resonator and to emit the light through an emission surface. The emission surface has a dielectric function that varies spatially according to a pattern.

In another aspect of the invention, the laser comprises a resonator designed to confine, at least in part, light propagating within the waveguide and an extraction region laterally separated from the resonator. The extraction region is configured to receive light from the resonator and to emit the light through an emission surface.

In another aspect of the invention, the laser comprises a method. The method comprises propagating light in a resonator and introducing the light into an extraction region separate from the resonator. The method further comprises emitting the light from a surface of the extraction region. The surface has a dielectric function that varies according to a pattern.

Other aspects, embodiments and features of the invention will become apparent from the following detailed description of the invention when considered in conjunction with the accompanying drawings. The accompanying figures are schematic and are not intended to be drawn to scale. In the figures, each identical, or substantially similar component that is illustrated in various figures is represented by a single numeral or notation. For purposes of clarity, not every component is labeled in every figure. Nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions, will control.

### BRIEF DESCRIPTION OF DRAWINGS

FIGS. 1A and 1B are a cross-section and a top view of a laser structure according to an embodiment of the invention.

FIG. 2 is a cross-section of a laser structure according to an embodiment of the invention.

FIG. 3 shows a laser structure according to an embodiment of the invention.

FIG. 4 is a top view of a laser structure according to an embodiment of the invention.

### DETAILED DESCRIPTION

Laser structures and related methods are provided. The lasers may be formed of semiconductor materials with most (or all) of the components being formed on a unitary structure. The lasers include a resonator (e.g., a waveguide) which confines light and may be formed, for example, between two reflective regions or surfaces. During operation, light is generated and introduced into the resonator where it propagates and gains power as photons are generated within the material in the resonator. Eventually, a portion of the light passes into a light extraction region from which it is emitted in the form of a coherent beam of light. In some embodiments, the light extraction region has an emission surface having a dielectric function that varies spatially according to a pattern which can enhance light extraction. As described further below, the light extraction region may be laterally separated from the resonator and/or configured to emit the light vertically from the emission surface. Amongst other advantages, the lasers can emit light having desirable emission characteristics (e.g., high power) and may have a relatively simple structure which can facilitate processing and quality control testing.

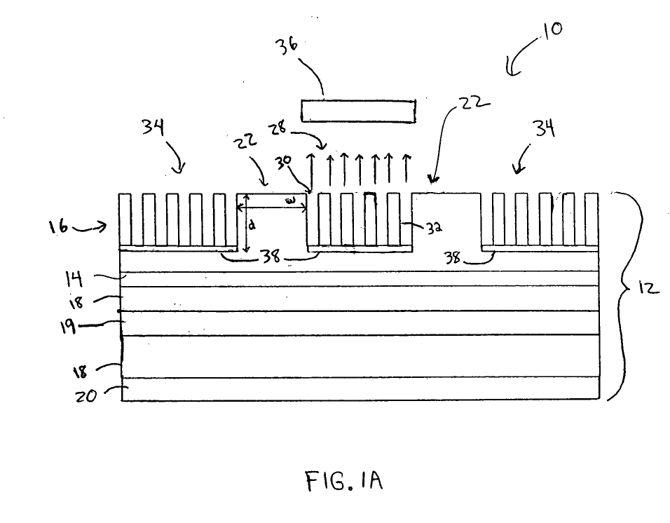

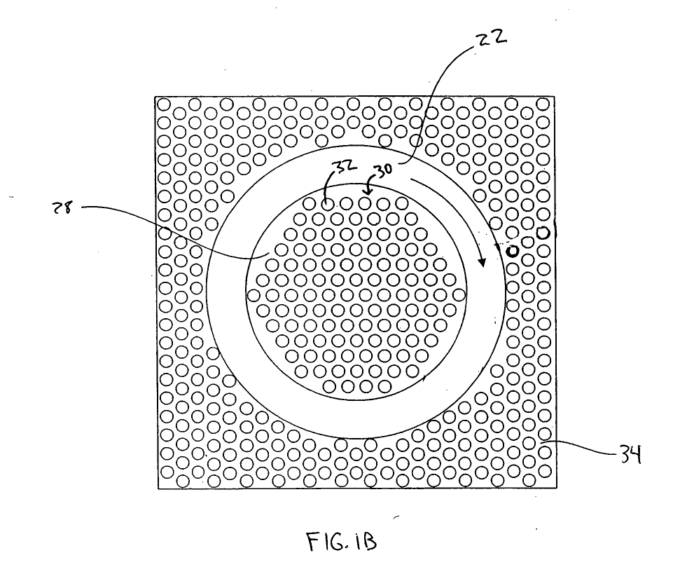

FIGS. 1A and 1B illustrate a laser diode 10 according to one embodiment of the invention. The laser includes a multi-layer stack 12 that may be disposed on a sub-mount (not shown). The multi-layer stack can include an active region 14 which generates light. The active region is formed between an n-doped layer(s) 16 and a p-doped layer(s) 18 in this embodiment. In this embodiment, the stack includes a low refractive index material layer 19 below the active region. The stack can also include an electrically conductive layer 20 which may serve as a p-side contact. An n-side contact pad may be disposed on the n-doped layer, though it is not shown. A resonator 22 (e.g., a waveguide) is formed above the active region. As described further below, a light extraction region 28 is separated from the resonator and configured to receive light from the resonator and emit light through an emission surface 30. In the illustrative embodiment, the emission surface has a dielectric function that varies spatially according to a pattern which is formed by a plurality of openings 32 in the surface. The pattern may enhance light extraction, amongst other advantages. As shown, a peripheral region 34 surrounding the resonator also includes openings. In the illustrative embodiment, a non-linear crystal region 36 is positioned above the emission surface and may convert the frequency of the emitted light to a desired value. Reflective regions 38 may be formed beneath the peripheral region and the light extraction region to limit the light generated by the active region that passes directly into those regions.

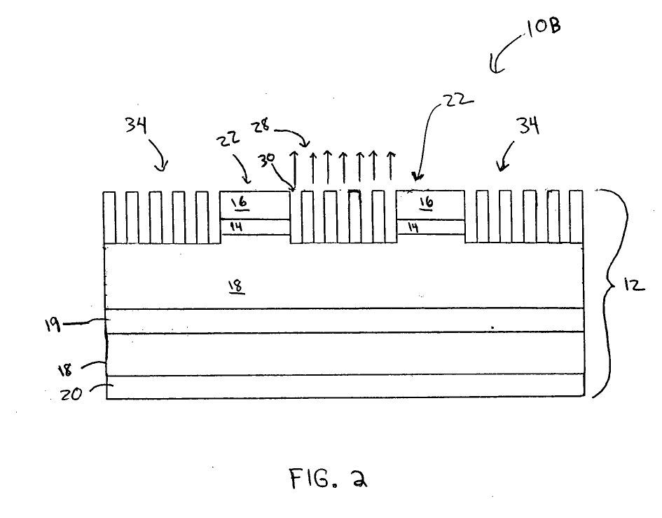

FIG. 2 shows a laser diode 10B according to another embodiment of the invention. In the embodiment of FIG. 2, the active region is positioned within the resonator. This configuration may enhance the amount of generated light that passes into and propagates within the resonator. It should be understood that the active region may be positioned in other locations including directly beneath the resonator. The embodiment of FIG. 2 does include reflective regions 38 formed beneath the peripheral region and the light extraction region.

It should be appreciated that the laser is not limited to the structure shown in the figures. For example, the n-doped and p-doped sides may be interchanged so as to form a laser having a p-doped region formed on the active region and an n-doped region formed under the active region. In some cases, one or more additional material layers may be formed on the emission surface. In some embodiments, the non-linear crystal region, low refractive index material layer, and/or reflective regions 38 are not present. Other variations are also possible.

During use, electrical potential may be applied to the contact pads which can result in light generation within the active region. At least some, and preferably, a majority of the generated light enters the resonator. Light is confined and propagates within the resonator (e.g., following the direction of the arrow in FIG. 1A). Eventually, a portion of the light passes from the resonator into the light extraction region. The light is emitted from the light extraction region through the emission surface. In these embodiments, the light is emitted in a substantially vertical direction from the emission surface.

Active region 14 can include one or more quantum wells surrounded by barrier layers. The quantum well structure may be defined by a semiconductor material layer (e.g., in a single quantum well), or more than one semiconductor material layers (e.g., in multiple quantum wells), with a smaller band gap as compared to the barrier layers. Suitable semiconductor material layers for the quantum well structures can include InGaN, AlGaN, GaN and combinations of these layers (e.g., alternating InGaN/GaN layers, where a GaN layer serves as a barrier layer). In general, the lasers can include an active region comprising one or more semiconductors materials, including III-V semiconductors (e.g., GaAs, AlGaAs, AlGaP, GaP, GaAsP, InGaAs, InAs, InP, GaN, InGaN, InGaAlP, AlGaN, as well as combinations and alloys thereof), II-VI semiconductors (e.g., ZnSe, CdSe, ZnCdSe, ZnTe, ZnTeSe, ZnS, ZnSSe, as well as combinations and alloys thereof), and/or other semiconductors.

N-doped layer(s) 16 can include a silicon-doped GaN layer (e.g., having a thickness of about 300 nm thick) and/or p-doped layer(s) 18 include a magnesium-doped GaN layer (e.g., having a thickness of about 40 nm thick). The electrically conductive layer 20 may be a silver layer (e.g., having a thickness of about 100 nm). The low refractive index material layer 19 may be a dielectric material such as an oxide or a nitride (e.g., AlN) material. Furthermore, although not shown, other layers may also be included in the laser; for example, an AlGaN layer may be disposed between the active region and the p-doped layer(s). It should be understood that compositions other than those described herein may also be suitable for the layers.

Light may be generated by the active region as follows. The p-side contact layer can be held at a positive potential relative to the n-side contact pad, which causes electrical current to be injected into the active region. As the electrical current passes through the active region, electrons from n-doped layer(s) can combine in the active region with holes from p-doped layer(s), which can cause the active region to generate light. The active region can contain a multitude of point dipole radiation sources that generate light with a spectrum of wavelengths characteristic of the material from which the active region is formed. For InGaN/GaN quantum wells, the spectrum of wavelengths of light generated by the light-generating region can have a peak wavelength of about 445 nanometers (nm) and a full width at half maximum (FWHM) of about 30 nm, which is perceived by human eyes as blue light.

In other embodiments, the active region can generate light having a peak wavelength corresponding to ultraviolet light (e.g., having a peak wavelength of about 370-390 nm), violet light (e.g., having a peak wavelength of about 390-430 nm), blue light (e.g., having a peak wavelength of about 430-480 nm), cyan light (e.g., having a peak wavelength of about 480-500 nm), green light (e.g., having a peak wavelength of about 500 to 550 nm), yellow-green light (e.g., having a peak wavelength of about 550-575 nm), yellow light (e.g., having a peak wavelength of about 575-595 nm), amber light (e.g., having a peak wavelength of about 595-605 nm), orange light (e.g., having a peak wavelength of about 605-620 nm), red light (e.g., having a peak wavelength of about 620-700 nm), and/or infrared light (e.g., having a peak wavelength of about 700-1200 nm).

As noted above, at least some of the generated light passes into the resonator. The resonator may be formed of any suitable material and, for example, may be formed of the same material as n-doped layer. In the embodiment of FIG. 1A, the resonator is contained within the n-doped layer in this embodiment, though may extend into other layers/regions in other embodiments (e.g., FIG. 2). Suitable materials include those that may provide a sufficient gain to light that propagates within the resonator.

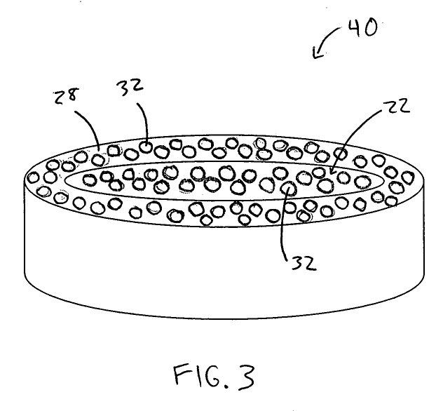

In FIGS. 1-2, the resonator is ring-shaped. The ring-shape may be continuous as shown, or may be formed by discontinuous portions that are aligned in a ring. However, it should be understood that the resonator may have other suitable shapes including a disc. Also, as shown in FIG. 3 and described further below, the laser includes a resonator that surrounds a plurality of openings.

The resonator may have any suitable dimensions. For example, the resonator may have a width (w) of between about 1 micron and about 10 microns (e.g., 2.5 microns) and a depth (d) of between about 100 nm and 1 micron (e.g., 500 nm). In embodiments that include a ring-shaped resonator, the ring may have a diameter of between about 0.05 mm to 0.5 mm (e.g., 0.1 mm).

In some cases, it may be preferable for the resonator to lie substantially within a lateral plane of the device (e.g., the lateral plane defined by the n-doped layer) which causes light to propagate substantially within this plane.

In some embodiments, it is preferable for the resonator to be a waveguide (e.g., a ridge waveguide).

In the illustrated embodiments, the light extraction region is separated from the resonator within the same unitary structure. That is, the light extraction region is physically separated from the resonator and located at different position within the structure. For example, the resonator may be adjacent to the extraction region. In some cases, it is preferable that the extraction region be laterally separated from the resonator as shown. The resonator and the extraction region may lie in the same plane which, for example, may be in a horizontal (i.e., lateral) that extends across the laser. In some case, the emission surface of the extraction region may be aligned with the upper surface of the resonator.

A portion of the light propagating in the resonator passes into the extraction region. In some cases, the light may preferentially pass from the resonator into the extraction region, rather than into the peripheral region, because of lower index of refraction differences between the resonator and the extraction region than differences between the resonator and the peripheral region. The emission surface of the extraction region may be patterned with a plurality of openings, as described above. This patterning, amongst other effects described further below, may enhance emission in a substantially vertical direction through the emission surface. Thus, light may propagate in the resonator substantially within a plane, while being emitted through the emission surface in a direction substantially perpendicular to that plane. Emission may be substantially uniform across the emission surface. This may distinguish lasers of the invention from certain conventional lasers which have localized emission through the emission surface which is dependent on the structure of those lasers.

As a result of openings 32, the emission surface can have a dielectric function that varies spatially according to a pattern which can influence the extraction efficiency and collimation of light emitted by the laser. In the illustrative laser, the pattern is formed of openings, but it should be appreciated that the variation of the dielectric function at an interface need not necessarily result from openings. Any suitable way of producing a variation in dielectric function according to a pattern may be used. For example, the pattern may be formed by varying the composition of n-doped layer 16 and/or emission surface 30. The pattern may be periodic (e.g., having a simple repeat cell, or having a complex repeat super-cell) or non-periodic (e.g., a de-tuned pattern). As referred to herein, a complex periodic pattern is a pattern that has more than one feature in each unit cell that repeats in a periodic fashion. Examples of complex periodic patterns include honeycomb patterns, honeycomb base patterns, (2×2) base patterns, ring patterns, and Archimidean patterns. In some embodiments, a complex periodic pattern can have certain openings with one diameter and other openings with a smaller diameter. As referred to herein, a non-periodic pattern is a pattern that has no translational symmetry over a unit cell that has a length that is at least 50 times the peak wavelength of light generated by the active region. Examples of non-periodic patterns include aperiodic patterns, quasi-crystalline patterns, Robinson patterns, and Amman patterns. A non-periodic pattern can also include random surface roughness patterns having a root-mean-square (rms) roughness about equal to an average feature size which may be related to the wavelength of the emitted light.

Suitable surfaces having a dielectric function that varies spatially according to a pattern (e.g., a photonic lattice) have been described in, for example, U.S. Pat. No. 6,831,302 B2, entitled “Light Emitting Devices with Improved Extraction Efficiency,” filed on Nov. 26, 2003, which is herein incorporated by reference in its entirety.

It should also be understood that other patterns are also possible, including a pattern that conforms to a transformation of a precursor pattern according to a mathematical function, including, but not limited to an angular displacement transformation. The pattern may also include a portion of a transformed pattern, including, but not limited to, a pattern that conforms to an angular displacement transformation. The pattern can also include regions having patterns that are related to each other by a rotation. A variety of such patterns are described in U.S. patent application Ser. No. 11/370,220, entitled “Patterned Devices and Related Methods,” filed on Mar. 7, 2006, which is herein incorporated by reference in its entirety.

In some embodiments, the laser may include a non-linear crystal region 36 above the emission surface which converts the frequency of the emitted light to a desired value. However, it should be understood that the non-linear crystal region is optional and that lasers of the invention may not include a non-linear crystal region. When present, any suitable non-linear crystal composition may be used including lithium niobate (LiNbO₃), lithium tantalate (LiTaO₃), potassium titanyl phosphate (KTP, KTiOPO₄) and potassium dihydrogen phosphate (KDP, KH₂PO₄), amongst others. In some embodiments, the non-linear crystal region doubles the frequency of the emitted light (e.g., when it is a frequency doubling crystal region). In some embodiments, the non-linear crystal region may have a dielectric function that varies according to the patterns described above. For example, the pattern may comprise a plurality of openings in the surface of the non-linear crystal region. In embodiments that include a non-linear crystal region, an upper mirror (not shown) may be positioned on the region so that a second resonator is formed. When present, the upper mirror may be made of a non-absorbing material region including a distributed Bragg reflector.

FIG. 3 shows a laser 40 according to another embodiment of the invention. In this embodiment, resonator 22 is the material that surrounds openings 32. The openings may be arranged in a pattern, as described above. In the embodiment of FIG. 3, the laser may operate in “whispering gallery” mode. As shown, extraction region 30 surrounds the resonator in this embodiment. Similar to the embodiments described above, light passes from the resonator to the light extraction region from which it is emitted through an emission surface which also may include a pattern of openings.

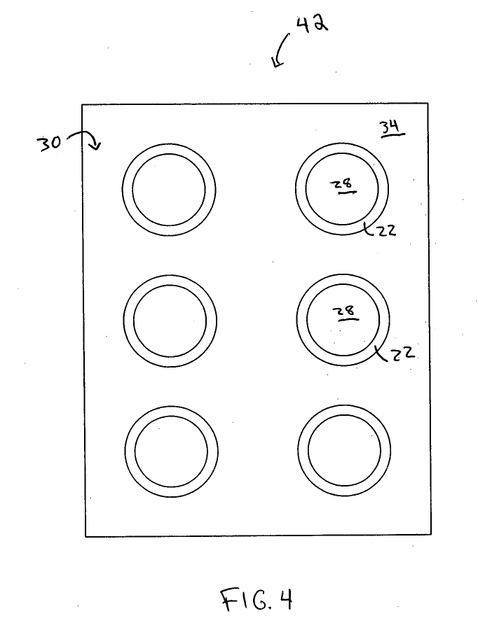

FIG. 4 shows a laser 42 according to an embodiment of the invention. Laser 42 includes an array of resonators 22. Each resonator is coupled to respective extraction regions 28, as described above. Although not shown in FIG. 4, the extraction regions may include a pattern of openings as described above. It should be understood that lasers of the invention may include any suitable number of resonators. In some embodiments, resonators may be positioned close enough to one another so that light can propagate between the resonators. In such embodiments, it may be possible for the light emitted from each extraction region to form a coherent (i.e., in phase) beam.

Advantageously, the lasers described herein can emit light having desirable characteristics. For example, the light may have a high power (e.g., greater than 0.5 W) and or be highly collimated. The lasers have a relatively simple structure which can facilitate processing. Furthermore, the surface emission capability of the lasers simplifies quality control testing. For example, the performance of each laser die on a wafer may be characterized while the die are still on the wafer.

Lasers of the invention may be used in a wide variety of applications. Applications for which the lasers are particularly well-suited are in areas of displays, data transfer through fiber optics, and optical media.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A laser comprising:
a resonator designed to confine, at least in part, light propagating within the waveguide; and
an extraction region separated from the resonator, the extraction region configured to receive light from the resonator and to emit the light through an emission surface, the emission surface having a dielectric function that varies spatially according to a pattern.

2. The laser of claim 1, wherein the extraction region is laterally separated from the resonator.

3. The laser of claim 1, wherein the resonator and the extraction region are in a first plane.

4. The laser of claim 3, wherein the plane is in a lateral direction.

5. The laser of claim 1, wherein the emission surface is aligned with an upper surface of the resonator.

6. The laser of claim 1, wherein the resonator is a waveguide.

7. The laser of claim 1, wherein the resonator has a ring shape.

8. The laser of claim 1, wherein the resonator surrounds the extraction region.

9. The laser of claim 1, further comprising a peripheral region surrounding the resonator.

10. The laser of claim 9, wherein a surface of the peripheral region has a dielectric function that varies spatially according to a pattern.

11. The laser of claim 1, wherein the light is emitted through the emission surface in a substantially vertical direction.

12. The laser of claim 11, wherein the substantially vertical direction is substantially parallel to the emission surface.

13. The laser of claim 1, further comprising a light-generating region coupled to the resonator such that light generated by the light-generating region may propagate within the resonator.

14. The laser of claim 1, wherein the resonator and the extraction region comprise semiconductor materials.

15. The laser of claim 1, wherein the resonator and the extraction region are part of a unitary structure.

16. The laser of claim 1, comprising an array of resonators.

17. The laser of claim 16, wherein more than one resonator in the array are arranged such that light may propagate between the resonators.

18. The laser of claim 16, wherein each resonator is associated with an extraction region and light emitted from each respective extraction region forms a coherent beam.

19. The laser of claim 1, wherein the pattern is non-periodic.

20. A laser comprising:
a resonator designed to confine, at least in part, laser light propagating within the resonator; and
an extraction region laterally separated from the resonator, the extraction region configured to receive light from the resonator and to emit the light through an emission surface.

21. The laser of claim 20, wherein the resonator and the extraction region are in a first plane.

22. The laser of claim 20, wherein the resonator and the extraction region comprise semiconductor materials.

23. The laser of claim 20, wherein the resonator and the extraction region are part of a unitary structure.

24. The laser of claim 20, wherein the resonator has a ring shape and surrounds the extraction region.

25. A method comprising:
propagating light in a resonator;
introducing the light into an extraction region separate from the resonator; and
emitting the light from a surface of the extraction region, wherein the surface has a dielectric function that varies according to a pattern.
